(19) United States
(12) Patent Application Publication
(10) Pub. No.: US 2015/0315721 A1
(43) Pub. Date: Nov. 5, 2015

(54) ONE STEP SYNTHESIS OF CORE/SHELL NANOCRYSTAL QUANTUM DOTS

(71) Applicants: Xinhua ZHONG, (US); Wenjin ZHANG, (US)

(72) Inventors: Xinhua ZHONG, Shanghai (CN); Wenjin ZHANG, Shanghai (CN)

(21) Appl. No.: 14/651,116

(22) PCT Filed: Dec. 10, 2012
(86) PCT No.: PCT/CN2012/086294

§ 371 Date: Jun. 10, 2015

(51) Int. Cl. C30B 7/14; C30B 29/48; H01L 21/02; C30B 29/50

(52) U.S. Cl. CPC C30B 7/14; C30B 29/50; C30B 29/48; H01L 21/02601; H01L 21/02628; H01L 21/02557

(57) ABSTRACT

Disclosed herein are compositions and one-step synthesis of core/shell nanocrystal quantum dots. In an embodiment, a method of making a nanocrystal includes mixing at least one cationic precursor, at least one anionic precursor, and at least one solvent to form a mixture, heating the mixture, precipitating the mixture to form a nanocrystal precipitate, and isolating the nanocrystal precipitate. The formed nanocrystal comprises an outer shell encapsulating an inner core and exhibits substantial crystallinity, monodispersity, and reproducibility.

### BACKGROUND

Semiconductor nanocrystals have been a subject of great interest, promising extensive application in display devices, information storage, biological tagging materials, photovoltaics, sensors and catalysts. Nanocrystals having small diameters can have properties that are in between molecular and bulk forms of matter. For example, nanocrystals based on semiconductor materials having small diameters can exhibit quantum confinement of both the electron and the hole in all three dimensions, which leads to an increase in the effective band gap of the material with decreasing crystallite size. Consequently, both the optical absorption and emission of nanocrystals shift towards wavelengths with higher energies as the size of the crystallites decreases.

Although the use of semiconductor nanocrystal quantum dots (QDs) in a wide array of applications is appreciated, its full potential has not been realized yet, in part due to synthesis procedures that lack scalability and high reproducibility. It is well known that the fluorescence of the nascent core nanocrystals are not stable and are sensitive to environmental changes, surface chemistry, and photo-oxidation. To overcome these shortcomings, recent efforts have focused on the development of core/shell structure via epitaxially overcoating a shell of semiconductor materials around the core nanocrystals having a wider band gap. The shell is generally thought to passivate the outermost surface of a core nanocrystal, thereby reducing or eliminating the surface energy states associated with the core and insulating the core from the outside environment. This can reduce or eliminate the non-radiative loss of photons from the core to the environment, preserving the efficient fluorescence properties of the core. Such shell deposition can accordingly improve the stability of the nanocrystals and photoluminescence quantum efficiency (PL QY), which are important prerequisites for the practical application of nanocrystals.

Typically, core/shell QDs are fabricated by a two-step procedure: initial synthesis of core QDs, mostly relying on “hot-injection method” by rapid injection of precursors into hot reaction media, followed by a shell growth reaction by either dropwise or successive ion layer adsorption reaction method. Unfortunately, neither the hot-injection-based synthetic method for core nanocrystals nor the shell deposition procedure are suitable for large-scale preparation. The essential components in the synthesis of core/shell QDs typically include expensive, pyrophoric, and/or toxic tertiary phosphine chalcogenides, hexamethyldisilathiane, and organometallic compounds, such as CdMe₂ and ZnEt₂ as the reactive precursors. This renders the synthesis of core/shell QDs expensive, labor-intensive, and time-consuming. In addition to high cost, the harsh operating conditions involved during the synthesis also impede the practical application of QDs. It is highly desirable to develop synthetic methods that are aimed at producing high-quality core/shell QDs for potential applications, and methods which are scalable, reproducible, environmentally friendly, and low cost.

### SUMMARY

The present work discloses compositions and one-step synthesis of core/shell nanocrystal quantum dots. In an embodiment, a method of making a nanocrystal includes mixing at least one cationic precursor, at least one anionic precursor, and at least one solvent to form a mixture, heating the mixture, precipitating the mixture to form a nanocrystal precipitate and isolating the nanocrystal precipitate. The formed nanocrystal comprises an outer shell encapsulating an inner core and exhibits substantial crystallinity, monodispersity, and reproducibility.

In additional embodiment, a nanocrystal comprising an outer shell encapsulating an inner core may be formed by a process comprising the steps of contacting a solvent comprising a mixture of trioctylphosphine, stearic acid, and 1-octadecene with at least one cationic precursor, and at least one anionic precursor to form a mixture, heating the mixture, precipitating the mixture to form a nanocrystal precipitate and isolating the nanocrystal precipitate.

### BRIEF DESCRIPTION OF THE FIGURES

FIG. 1a depicts a temporal evolution of UV-visible (solid lines) and PL (dashed lines, λₑₓ=350 nm) spectra of CdSe/ZnₓCd₁₋ₓS QDs grown at 250° C. according to an embodiment. FIG. 1b shows the summary of PL peak positions and QYs of the obtained QDs under different growth times according to an embodiment.

FIG. 2a shows a PL emission spectra of obtained core/shell QDs with emission wavelength spanning from violet to near-infrared window according to an embodiment. FIG. 2b depicts photographs of typical emission colors from the obtained QDs under the irradiation of a UV lamp.

FIG. 3a-d show wide-field TEM images of CdSe/ZnₓCd₁₋ₓS QD samples taken at 170° C. (a), and at 250° C. with growth time of 0 minutes (b), 30 minutes (c), and 2 hours (d) according to an embodiment. FIG. 3e shows a high resolution TEM image of the sample in FIG. 3d. Insets are the corresponding histograms of the size distribution.

### DETAILED DESCRIPTION

This disclosure is not limited to the particular systems, devices and methods described, as these may vary. The terminology used in the description is for the purpose of describing the particular versions or embodiments only, and is not intended to limit the scope.

Disclosed herein are low-cost, reproducible and scalable processes for manufacturing high-quality core/shell QDs with emission wavelengths from about 400 nanometers to about 2000 nanometers. Disclosed method include a “non-injection or heating-up method”, wherein all reagents are loaded in a single reaction pot at room temperature and subsequently heated to a reflux for nanocrystals nucleation, growth and shell formation. In certain embodiments, the disclosed methods advantageously exclude the multiple-step synthesis of core/shell QDs. In some embodiments, the method involves directly heating the reaction mixture composed of at least one cationic precursor, at least one anionic precursor, and at least one solvent. In some embodiments, the cationic precursors may be a group II metal, a group III metal, a group IV metal, and compounds may be in the form of a metal oxide, a metal carbonate, a metal bicarbonate, a metal sulfate, a metal sulfite, a metal phosphate, a metal phosphite, a metal halide, a metal carboxylate, a metal hydroxide, a metal alkoxide, a metal thiolate, a metal amide, a metal imide, a metal alkyl, a metal aryl, a metal coordination complex, a metal solvate, a metal salt, or a combination thereof. Exemplary compounds include CdO, Zn(NO₃)₂, Zn(OAc)₂, Mg(NO₃)₂, CaCl₂, Mg(OAc)₂, and the like.

The source of the anionic precursors may be a group V metal, a group VI metal, or a combination thereof. The anionic precursor may be a covalent compound or an ionic compound of group V and group VI metals. Exemplary anionic precursors include S, Se, Te, P, N, As, Sb, and the like.

The cationic precursor and the anionic precursor are mixed in a solvent mixture in a reaction vessel. The solvent mixture may be a mixture of one, two, or more coordinating solvents, non-coordinating solvents and passivating agents. A coordinating solvent may help control the growth of the nanocrystal and which form a passivating layer on the nanocrystal surface. The coordinating agent is a compound having a donor lone pair that, for example, has a lone electron pair available to coordinate to a surface of the growing nanocrystal. Typical coordinating solvents include phosphines, phosphine oxides, phosphonic acids, phosphinic acids, long chain carboxylic acids, amines, thiols, polyethylene glycol, pyridines, furans, and combinations thereof. Examples of suitable coordinating agents include pyridine, trioctyl phosphine (TOP) and trioctyl phosphine oxide (TOPO). In some embodiments, the coordinating solvent such as a phosphine and a cationic precursor are in the ratio of present in a weight to weight ratio from about 0.001:1 to about 10:1, about 0.01:1 to about 10:1, about 0.1:1 to about 10:1, about 1:1 to about 10:1, about 2:1 to about 10:1, or about 5:1 to about 10:1. Specific examples include about 0.001:1, about 0.1:1, about 1:1, about 2:1, about 4:1, about 6:1, about 10:1, and ranges between any two of these values.

In some embodiments, the solvent mixture includes one or more non-coordinating solvents, such as 1-octadecene, octadecane, tetradecane, squalane, and combinations thereof.

To solubilize the cationic precursor in the non-coordinating solvent mixture, it may be useful to add one or more long chain carboxylic acids such as butyric acid, caproic acid, caprylic acid, capric acid, lauric acid, myristic acid, palmitic acid, margaric acid, stearic acid, arachidic acid, behenic acid, lignoceric acid, myristoleic acid, palmitoleic acid, gadoleic acid, erucic acid, nervonic acid, linoleic acid, linolenic acid, parinaric acid, aracidonic acid, timnodonic acid, brassic acid, clupanodonic acid, and combinations thereof. In some embodiments, the long chain carboxylic acid and the cationic precursor may be present in a weight to weight ratio of about 1:1 to about 4:1, about 2:1 to about 4:1, or about 4:1 to about 4:1. Specific examples include about 1:1, about 2:1, about 3:1, about 4:1, and ranges between any two of these values. Variations in the amount of coordinating solvents and/or long chain carboxylic acids in the reaction mixture may influence the particle size and composition of the nanocrystal QDs, and therefore influence their emission wavelengths. By such variations, the emission wavelengths of the resulting QDs may be tuned from about 400 nanometers to about 2000 nanometers inclusively.

The cationic precursor, the anionic precursor and the solvent mixture may be heated to initiate the formation of crystals. In some embodiments, the reaction mixture may be heated in air. In some embodiments, the reaction mixture may be degassed prior to the heating step. In some embodiments, the heating performed under inert conditions. Suitable heating temperature ranges include from about 170° C. to about 300° C., about 200° C. to about 300° C., about 225° C. to about 300° C., or about 250° C. to about 300° C. Specific examples include about 170° C., about 200° C., about 220° C., about 240° C., about 260° C., about 300° C., and ranges between any two of these values (including endpoints). The reaction mixture may be heated at a rate of about 2° C. per minute to about 50° C. per minute, about 8° C. per minute to about 50° C. per minute, about 15° C. per minute to about 50° C. per minute, or about 25° C. per minute to about 50° C. per minute. Specific examples include about 2° C. per minute, about 10° C. per minute, about 15° C. per minute, about 25° C. per minute, about 35° C. per minute, about 50° C. per minute, and ranges between any two of these values (including endpoints).

The reaction mixture may be heated for generally any amount of time, such as about 30 minutes to about 4 hours, about 1 hour to about 4 hours, about 2 hours to about 4 hours, or about 3 hours to about 4 hours. Specific examples include about 30 minutes, about 45 minutes, about 1 hour, about 1.5 hours, about 2.5 hours, about 4 hours, and ranges between any two of these values (including endpoints). An exemplary method of preparing a core/shell nanocrystal, such as CdSe/ZnₓCd₁₋ₓS may involve mixing CdO, Zn(NO₃)₂, Se and S in a solvent mixture of trioctylphisphine, octadecene and stearic acid and heating the reaction mixture in air to a temperature of about 250° C. for 2 hours.

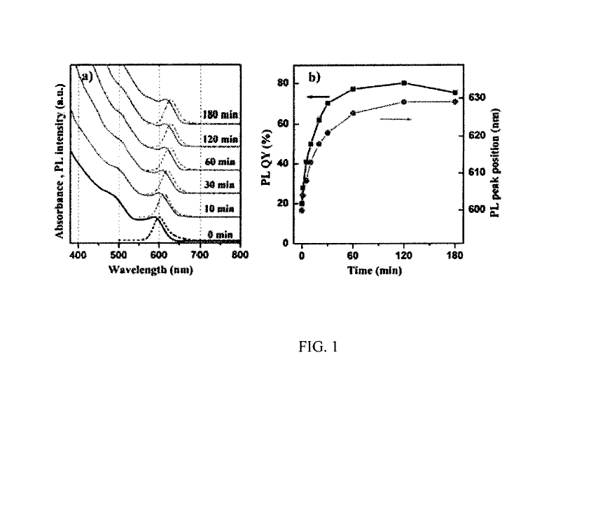

The growth of the nanocrystals during the reaction may be monitored by taking aliquots of the reaction mixture and recording the UV-visible absorption spectra and photoluminescence (PL) emission spectra at various intervals. Spectral characteristics of nanocrystals can generally be monitored using any suitable light-measuring or light-accumulating instrumentation. Examples of such instrumentation are CCD (charge-coupled device) cameras, video devices, CIT imaging, digital cameras mounted on a fluorescent microscope, photomultipliers, fluorometers and luminometers, microscopes of various configurations, and even the human eye. The emission can be monitored continuously or at one or more discrete time points. A UV-visible spectra and PL spectra of an exemplary nanocrystal CdSe/ZnₓCd₁₋ₓS that was monitored during the preparation is shown in FIG. 1.

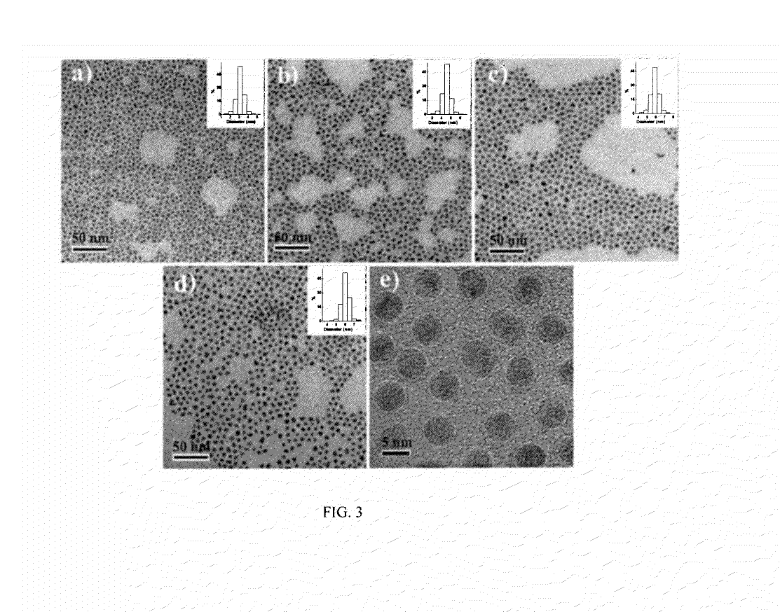

The nucleation rate of the nanocrystal may be varied by varying the reaction temperatures and heating periods. Modification of the reaction temperature in response to changes in the absorption spectrum of the particles allows the maintenance of a sharp particle size distribution during growth. In some embodiments, heating the reaction mixture at different temperatures may result in formation of core/shell nanocrystals of different sizes. For example, during synthesis the CdSe/ZnₓCd₁₋ₓS nanocrystal at different growth stages may display a mean diameter increasing from 3.1±0.2 nm (at 170° C.) to 4.6±0.3 nm (0 min at 250° C.), 5.9±0.3 nm (30 min at 250° C.) and 6.1±0.3 nm (2 h at 250° C.) as the reaction proceeds. Representative transmission electron microscopy images of the nanocrystals are shown in FIG. 3.

In additional embodiments, the formed QDs may be a pseudo core/shell structure with the shell material composed of a gradient of alloy of a group I-III-VI compound, a group II-IV-VI compound, a group II-IV-V compound. For example, in a CdSe/ZnₓCd₁₋ₓS nanocrystal the core may be composed of Cd and Se, and the outer shell may be composed of Cd, Zn and S, and the amounts of Cd and Se in the core may decrease radially outward, and the amounts of Zn and S may increase. In some embodiments, a partial alloying process may take place between the core and the shell interface, and the clear core-shell interface may be difficult to observe. Such gradient alloy shell layers may efficiently relieve the interface strain caused by the lattice mismatch between CdSe and ZnS, and thus favor high quantum yields.

By using the single-step non-injection methods described herein, the emission wavelengths of core/shell nanocrystal QDs may be conveniently tuned. For example, the emission wavelength of the CdSe/ZnₓCd₁₋ₓS nanocrystal may be conveniently tuned from 500 nanometers to 680 nanometers by varying the amounts of trioctylphosphine and stearic acid, and the nature of zinc sources, such as Zn(OAc)₂ and Zn(NO₃)₂. Similarly, violet and blue emissions with wavelengths centered around 410 nanometers to about 460 nanometers may be obtained by reactions between CdO and elemental S in octadecene media containing stearic acid, with or without the presence of Zn(OAc)₂. Further, by replacing Se by an equal amount of Te in reaction mixtures, CdTe/ZnₓCd₁₋ₓS QDs may be obtained with corresponding emission wavelength located in the near-infrared window of about 650 nanometers to about 825 nanometers.

In some embodiments, the heated reaction mixture for producing the nanocrystals may be cooled at the end of the reaction to a temperature of about −50° C. to about −100° C., about −60° C. to about −100° C., about −70° C. to about −100° C., or about −80° C. to about −100° C. Specific examples of temperatures include about −50° C., about −60° C., about −70° C., about −80° C., about −100° C., and ranges between any two of these values (including endpoints). The cooling may be performed at a rate of about 2° C. per minute to about 30° C. per minute, about 5° C. per minute to about 30° C. per minute, about 10° C. per minute to about 30° C. per minute, about 15° C. per minute to about 30° C. per minute, or about 20° C. per minute to about 30° C. per minute. Specific examples of cooling rates include about 2° C. per minute, about 10° C. per minute, about 20° C. per minute, about 30° C. per minute, and ranges between any two of these values (including endpoints).

In some embodiments, at least one polar solvent may be added to the cooled mixture to precipitate the core/shell nanocrystals. Examples of a polar solvent that may be used include dichloromethane, tetrahydrofuran, ethyl acetate, acetone, dimethylformamide, acetonitrile, dimethyl sulfoxide, formic acid, methanol, ethanol, butanol, and combinations thereof. In additional embodiments, the precipitated nanocrystals may be isolated by centrifugation, to produce a pellet comprising precipitated nanocrystals in a supernatant. In these embodiments, the supernatant may be decanted, and the pellet comprising the precipitated nanocrystals may be washed with a non-polar solvent such as toluene, pentane, cyclopentane, hexane, cyclohexane, benzene, 1,4-dioxane, chloroform, or mixtures thereof. In some embodiments, the steps of centrifugation, decanting the solvent, and washing with a non-polar solvent may be repeated to produce a dispersion of suitably purified nanocrystals in the further solvent. The core/shell nanocrystals obtained as described herein may be dried in ambient conditions, by flowing gas, or under vacuum.

The quantum yield (QY) of the core/shell nanocrystal QDs obtained as described herein may be from about 60% to about 90%, about 70% to about 90%, about 80% to about 90%, or about 85% to about 90%. Specific examples include about 60%, about 65%, about 70%, about 75%, about 80%, about 85%, about 90%, about 95%, about 100% and ranges between any two of these values (including endpoints).

In some embodiments, the optical properties of the obtained core/shell QDs may be preserved for long periods of time at ambient atmosphere when dispersed in common nonpolar solvents. In addition, the optical properties of the QDs may be significantly retained when transferred into aqueous media through a ligand replacement method as detailed in Example 6. After phase transfer, the QDs in aqueous solutions may exhibit absorption and PL emission spectral profiles similar to the initial hydrophobic QD dispersions in nonpolar solvents.

In some embodiments, the nanocrystal QDs obtained by the methods disclosed herein may have a core semiconductor material surrounded by a shell made up of a second semiconductor material. The nanocrystal core material may be a group II-VI compound, a group II-V compound, a group compound, a group III-V compound, a group IV-VI compound, a group compound, a group II-IV-VI compound, a group II-IV-V compound, or combinations thereof. Suitable examples include, but are not limited to, CdSe, CdS, CdTe, ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, and PbTe.

In some embodiments, the nanocrystal QDs may have a shell material encapsulating the core material. The shell material may partially or completely encapsulate the core material. The shell material may generally have a wider band gap than the core, which enables it to protect the activated state that the core occupies when it has been photoactivated, forming a separated electron and hole. The shell may be chosen to have an atomic spacing and lattice structure that closely match those of the core material to best preserve the photophysical attributes of the core, since irregularities in the interface between core and shell may be responsible for non-radiative energy dissipation mechanisms that reduce luminescent efficiency. A suitable shell for a particular nanocrystal core may have a bandgap that is wider than the bandgap of the core, and that extends above the high end of the bandgap of the core and below the low end of the bandgap of the core. In certain embodiments, the shell may be composed of an insulating material or another semiconductive material such as a group II-VI compound, a group II-V compound, a group III-VI compound, a group III-V compound, a group IV-VI compound, a group I compound, a group II-IV-VI compound, a group II-IV-V compound, or combinations thereof. Suitable examples include, but are not limited to, CdS, CdSe, CdTe, ZnS, ZnSe, ZnTe, MgS, MgSe, MgTe, HgS, HgSe, HgTe, PbS, PbSe, PbTe, AlN, AlP, AlAs, AlSb, GaN, GaP, GaAs, GaSb, InN, InP, InAs, InSb, TlN, TlP, TlAs, and TlSb. In some embodiments, the shell material may be alloys of a semiconductive material such as ZnₓCd₁₋ₓS, MgCd₁₋ₓS, CaₓCd₁₋ₓS, SrₓCd₁₋ₓS, BaₓCd₁₋ₓS, HgₓCd₁₋ₓS, ScₓCd₁₋ₓS, AlCd₁₋ₓS, GaCd₁₋ₓS, InₓCd₁₋ₓS, MnₓCd₁₋ₓS, FeₓCd₁₋ₓS, NiₓCd₁₋ₓS, CuₓCd₁₋ₓS, MoₓCd₁₋ₓS, PdₓCd₁₋ₓS, AgₓCd₁₋ₓS, PtₓCd₁₋ₓS, AuₓCd₁₋ₓS, and combinations thereof.

For example, a nanocrystal QD may have a core material made from one or more of the following compounds: CdSe, CdS, CdTe, GaN, GaP, GaAs, GaSb, InN, InP, InAs, and InSb; and a shell material made from one or more of the following compounds: ZnₓCd₁₋ₓS, MgₓCd₁₋ₓS, CaₓCd₁₋ₓS, SrₓCd₁₋ₓS, BaₓCd₁₋ₓS, HgₓCd₁₋ₓS, ScₓCd₁₋ₓS, AlₓCd₁₋ₓS, GaCd₁₋ₓS, InₓCd₁₋ₓS, MoₓCd₁₋ₓS, AgₓCd₁₋ₓS, PtₓCd₁₋ₓS, AuₓCd₁₋ₓS, CdS, CdSe, CdTe, ZnS, ZnSe, ZnTe, MgS, MgSe, MgTe, HgS, HgSe, HgTe, PbS, PbSe, and PbTe. Exemplary core/shell nanocrystal QDs include CdSe/ZnₓCd₁₋ₓS, CdTe/ZnₓCd₁₋ₓS, CdS/ZnₓCd₁₋ₓS, GaN/CdS, GaP/CdS, GaAs/CdTe, GaSb/CdTe, InN/MgS, InAs/MgS, InSb/MgS, CdSe/MgₓCd₁₋ₓS, CdTe/MgₓCd₁₋ₓS, and CdS/MgₓCd₁₋ₓS.

Generally, core/shell nanocrystal QDs may have an average diameter of about 2 nanometers to about 10 nanometers, about 2 nanometers to about 9 nanometers, about 2 nanometers to about 8 nanometers, about 2 nanometers to about 6 nanometers or about 2 nanometers to about 4 nanometers. Specific examples of diameters include about 2 nanometers, about 3 nanometers, about 4 nanometers, about 5 nanometers, about 6 nanometers, about 7 nanometers, about 8 nanometers, about 9 nanometers, about 10 nanometers, and ranges between any two of these values (including endpoints).

In some embodiments, the core/shell nanocrystals may be substantially monodisperse. The term “monodisperse” refers to a population of particles having substantially identical size and shape. One of ordinary skill in the art will realize that particular sizes of nanocrystals are actually obtained as particle size distributions. For the purpose of the present disclosure, a “monodisperse” population of particles means that at least about 60% of the particles or, in some cases, about 75% to about 90%, about 95%, or about 100% of the particles, fall within a specific particle size range, and the particles deviate in diameter or largest dimension by less than 20% rms (root-mean-square) deviation and, in some cases, less than 10% rms deviation, and, in some cases, less than 5% rms deviation.

In some embodiments, the nanocrystals are identical in size and shape. Nanocrystals can be spherical or nearly spherical in shape, but can actually be any shape. Alternatively, the nanocrystals can be non-spherical in shape, such as rods, squares, discs, triangles, rings, tetrapods, or rectangular shapes.

The core/shell nanocrystal QDs of the current disclosure may exhibit an emission wavelength of about 400 nanometers to about 2000 nanometers, about 400 nanometers to about 1500 nanometers, about 400 nanometers to about 1000 nanometers, about 400 nanometers to about 800 nanometers, or about 400 nanometers to about 600 nanometers. Specific examples include about 400 nanometers, about 600 nanometers, about 800 nanometers, about 1000 nanometers, about 1200 nanometers, about 1400 nanometers, about 1600 nanometers, about 1800 nanometers, about 2000 nanometers, and ranges between any two of these values (including endpoints).

### EXAMPLES

### Example 1

### Synthesis of CdSe/Zn₁Cd₁₋ₓS QDs with Emission Wavelength Around 500 Nanometers

CdO (0.640 grams, 5 mmol), Zn(NO₃)₂.6H₂O (0.59 grams, 2 mmol), Se (100 mesh, 0.079 grams, 1 mmol), and S (0.064 grams, 2 mmol) were mixed with 7.0 mL of trioctylphosphine (TOP), 2.84 grams of stearic acid and 50 mL of 1-octadecene (ODE) in a 250 mL three-necked flask. The flask was fitted with a heating mantle, a condenser, and a temperature probe and placed on a stirplate. The mixture was heated to about 250° C. at a heating rate of about 5° C./minute to about 40° C./minute under air with vigorous stirring. During the reaction, aliquots were withdrawn with a syringe at different time points to monitor the growth of QDs by recording UV-visible absorption and PL emission spectra. At the end of the reaction, the reaction mixture was cooled to about −80° C. and precipitated by ethanol. The flocculent precipitate that was formed was centrifuged, the supernatant liquid was decanted, and the isolated solid was dispersed in toluene. The above centrifugation and dispersion steps were repeated several times to obtain QDs. The final product (0.850 grams) was dispersed in toluene, and dried under vacuum for further analysis.

### Example 2

### Synthesis of CdTe/ZnₓCd₁₋ₓS Core/Shell QDs with Emission Wavelength Around 650 Nanometers

CdO (0.640 grams, 5 mmol), Zn(CH₃COO)₂.2H₂O (0.440 grams, 2 mmol), Te (100 mesh, 0.128 grams, 1 mmol), and S (0.064 grams, 2 mmol) were mixed with 7.0 mL of trioctylphosphine (TOP), 2.84 grams of stearic acid, and 50 mL of octadecene in a 250 mL three-necked flask. The mixture was degassed at room temperature for 10 minutes. The reaction mixture was heated to about 250° C. at a heating rate of about 5° C./minute to about 40° C./minute under N₂ flow with vigorous stirring. During the reaction, aliquots were withdrawn with a syringe at different time points to monitor the growth of QDs by recording UV-visible absorption and PL emission spectra. The QDs were isolated as described in Example 1, and about 0.92 grams of dried QD product was obtained.

### Example 3

### Synthesis of CdS/ZnₓCd₁₋ₓS core/shell QDs with emission wavelength around 410 nanometers

CdO (0.640 grams, 5 mmol), Zn(OAc)₂.2H₂O (0.440 grams, 2 mmol), and S (0.064 grams, 2 mmol) were mixed with 2.84 grams of stearic acid and 50 mL of octadecene in a 250 mL three-necked flask. The mixture was degassed at room temperature for 10 minutes. The solution was heated to about 250° C. at a heating rate of about 5° C./minute to about 40° C./minute under N₂ flow with vigorous stirring. The reaction was monitored, and the QDs were isolated as described in Example 1. About 0.73 grams of dried QD product was obtained.

### Example 4

### Characterization of QDs

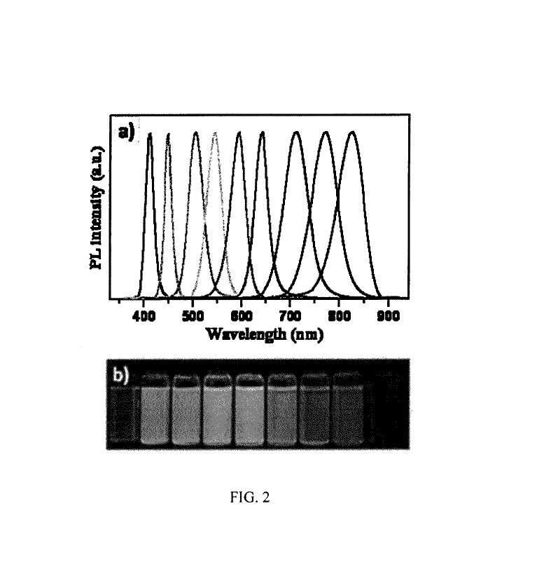

The QDs obtained (Examples 1-3) were characterized by measuring their optical properties. UV-visible and PL spectra were obtained using a Shimadzu UV-2450 spectrophotometer and a Cary Eclipse (Varian) fluorescence spectrophotometer, respectively. The room-temperature PL QY was determined by comparing the integrated emission of the QDs samples in chloroform with that of a fluorescent dye (such as Rhodamine 6 G with QY of 95% or Rhodamine 640 with QY of 100%) in ethanol with identical optical density. A quadratic refractive index correction was done in order to compensate the different refractive index of the different solvents used for organic dyes and QDs. FIG. 2 shows a representative PL emission spectra of a QD.

To conduct investigations in the transmission electron microscopy (TEM), the QDs were deposited from dilute toluene solutions onto copper grids with carbon support by slowly evaporating the solvent in air at room temperature. TEM and high resolution (HR) TEM images were acquired using a JEOL JEM-2010 transmission electron microscope (operating at an acceleration voltage of 200 kV), which was equipped with an energy-dispersive X-ray (EDX) detector. FIG. 3 shows representative TEM images of CdSe/ZnₓCd₁₋ₓS QDs. The TEM images show narrow size distribution of the as-prepared QDs and may not require further fractionation or sorting after synthesis.

### Example 5

### Methods to Tune the Emission Wavelength of QDs

The emission wavelengths of the QDs were tuned by varying the ratio of reaction components and reaction temperatures. The emission wavelength of the above obtained QD CdSe/ZnₓCd₁₋ₓS (Example 1) was changed from 500 nanometers to 680 nanometers by varying the reaction components. For example, when amount of TOP was varied between 0 mL and 0.93 mL, the emission wavelength of the QDs changed from 500 nanometers to 550 nanometers. Further, when the reaction mixture contained 0.93 mL of TOP and 15 mmol of stearic acid, QDs with an emission wavelength of 600 nanometers was obtained. Furthermore, when Zn(NO₃)₂ was replaced with Zn(OAc)₂ in the reaction mixture and stearic acid at 5 mmol, QDs with an emission wavelength of 680 nanometers was obtained. When Se was replaced with equal amount of Te, CdTe/ZnₓCd₁₋ₓS QDs with corresponding emission wavelength located in the near-infrared window of 650 nanometers to 825 nanometers were obtained.

Similarly, in Example 2, when the reaction temperature (230° C. to 250° C.) and reaction time (0-30 minutes) were varied, CdTe/ZnₓCd₁₋ₓS QDs with emission wavelengths between 650 nanometers to 800 nanometers were obtained. In Example 3, when the amount of Zn(OAc)₂ was varied in the reaction mixture, QDs with emission wavelengths between 410 nanometers to 450 nanometers were obtained. Table1 summarizes the experimental conditions and corresponding PL properties of core/shell QDs with different emission wavelengths.

TABLE 1

| emission | | | | | | | |
|---|---|---|---|---|---|---|---|
| wavelength | Zn source, | CdO, | chalcogenides, | TOP, | SA, | fwhm, | |
| (nm) | mmol | mmol | mmol | mL | mmol | nm | QY |
| 410-450 | Zn(OAc)₂, 0-0.8 | 1.6 | 0.8 S | 0 | 4.0 | 18-22 | 51-65 |
| 500-550 | Zn(NO₃)₂, 0.8 | 1.6 | 0.4 Se + 0.8 S | 0-0.4 | 4.0 | 26-28 | 62-75 |
| 550-600 | Zn(NO₃)₂, 0.8 | 1.6 | 0.4 Se + 0.8 S | 0.4 | 4.0-6.0 | 28-30 | 61-76 |
| 600-630 | Zn(NO₃)₂, 0.8 | 1.6 | 0.4 Se + 0.8 S | 3.0 | 4.0 | 30-31 | 58-82 |
| 620-680 | Zn(OAc)₂, 0.8 | 1.6 | 0.4 Se + 0.8 S | 3.0 | 4.0-2.0 | 31-36 | 55-83 |
| 650-820 | Zn(OAc)₂, 0.8 | 1.6 | 0.4 Te + 0.8 S | 3.0 | 4.0 | 33-60 | 30-65 |

These experiments demonstrate the versatility of the method in synthesizing QDs with variable emission wavelengths.

### Example 6

### Ligand replacement

Exchange of the native hydrophobic ligands on QDs surface by adenosine monophosphate (AMP) was performed as follows. About 1.0 grams (2.74 mmol) of AMP was dissolved in 3.0 mL of ethanol, and the pH of the resulting solution was adjusted to 10 with the use of concentrated NaOH solution. About 0.3 mL of the obtained AMP solution (containing 0.27 mmol AMP) in ethanol was added dropwise to isolated QDs dispersed in CHCl₃ (containing 1×10⁻⁶M QDs, 20.0 mL), and vigorously stirred for 30 minutes. Subsequently, deionized water was added into the solution. This resulted in transfer of QDs from the bottom organic phase to the top aqueous phase. The colorless organic phase was discarded and the aqueous phase containing the QDs was collected. The excess amount of free ligand was removed by centrifugation and washed with acetone. The supernatant was discarded, the pellet was re-dissolved in water, and the centrifugation-decantation process was repeated three times to obtain QDs in aqueous solutions. The QDs prepared according to this disclosure can be stored in aqueous solutions without appreciable loss of optical properties by using such methods.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

1. A method of making a nanocrystal quantum dot, the method comprising:
mixing at least one cationic precursor, at least one anionic precursor, and at least one solvent to form a mixture;
heating the mixture;
precipitating a nanocrystal quantum dot precipitate; and
isolating the nanocrystal quantum dot precipitate to obtain the nanocrystal quantum dot, wherein the nanocrystal quantum dot comprises an outer shell encapsulating an inner core and wherein the nanocrystal quantum dot exhibits substantial crystallinity, monodispersity, and reproducibility.

2. The method of claim 1, wherein the mixing comprises mixing the at least one cationic precursor selected from the group consisting of a group II metal, a group III metal, a group IV metal, and a combination thereof with the at least one anionic precursor and the at least one solvent.

3. The method of claim 1, wherein the mixing comprises mixing the at least one cationic precursor, the at least one solvent, and the at least one anionic precursor selected from the group consisting of a group V metal, a group VI metal, and a combination thereof.

4. The method of claim 1, wherein the mixing comprises mixing the at least one cationic precursor, the at least one anionic precursor, and the at least one solvent selected from the group consisting of a coordinating solvent, a non-coordinating solvent, and a combination thereof.

5. The method of claim 1, wherein the mixing comprises mixing the at least one cationic precursor, the at least one anionic precursor, and the at least one solvent comprising a coordinating solvent selected from the group consisting of a phosphine, a phosphine oxide, a phosphonic acid, a phosphinic acid, a long chain carboxylic acid, an amine, a thiol, polyethylene glycol, a pyridine, a furan and combinations thereof.

6. The method of claim 5, wherein the mixing comprises mixing the phosphine and the cationic precursor in a weight to weight ratio of about 0.001:1 to about 10:1.

7. The method of claim 1, wherein the mixing comprises mixing the at least one cationic precursor, the at least one anionic precursor, and the at least one solvent comprising a non-coordinating solvent selected from the group consisting of octadecene, octadecane, tetradecane, squalane, and combinations thereof.

8. The method of claim 1, wherein the mixing comprises mixing the at least one cationic precursor, the at least one anionic precursor, and the at least one solvent comprising a long chain carboxylic acid selected from the group consisting of butyric acid, caproic acid, caprylic acid, capric acid, lauric acid, myristic acid, palmitic acid, margaric acid, stearic acid, arachidic acid, behenic acid, lignoceric acid, myristoleic acid, palmitoleic acid, gadoleic acid, erucic acid, nervonic acid, linoleic acid, linolenic acid, parinaric acid, aracidonic acid, timnodonic acid, brassic acid, clupanodonic acid, and combinations thereof.

9. The method of claim 8, wherein the mixing comprises mixing the long chain carboxylic acid solvent and the cationic precursor in a weight to weight ratio of about 1:1 to about 4:1.

10. The method of claim 1, wherein the isolating comprises isolating the nanocrystal quantum dot precipitate to obtain the nanocrystal quantum dot, wherein the nanocrystal quantum dot comprises an outer shell encapsulating an inner core, and wherein the nanocrystal core is selected from the group consisting of a group II-VI compound, a group II-V compound, a group III-VI compound, a group III-V compound, a group IV-VI compound, a group compound, a group II-IV-VI compound, a group II-IV-V compound, and combinations thereof.

11. (canceled)

12. The method of claim 1, wherein the isolating comprises isolating the nanocrystal quantum dot precipitate to obtain the nanocrystal quantum dot, wherein the nanocrystal quantum dot comprises an outer shell encapsulating an inner core, and wherein the nanocrystal shell is selected from the group consisting of a group II-VI compound, a group II-V compound, a group III-VI compound, a group III-V compound, a group IV-VI compound, a group I compound, a group II-IV-VI compound, a group II-IV-V compound, and combinations thereof.

13. (canceled)

14. The method of claim 1, wherein the isolating comprises isolating the nanocrystal quantum dot precipitate to obtain the nanocrystal quantum dot, wherein the nanocrystal quantum dot comprises an outer shell encapsulating an inner core, and wherein the nanocrystal quantum dot has a core selected from the group consisting of CdSe, CdS, CdTe, GaN, GaP, GaAs, GaSb, InN, InP, InAs, InSb, ZnS, ZnSe, ZnTe, CdS, CdSe, CdTe, HgS, HgSe, HgTe, AlN, AlP, AlAs, AlSb, GaSe, TlN, TlP, TlAs, TlSb, PbS, PbSe, PbTe, and a combination thereof; and
a shell selected from the group consisting of ZnₓCd₁₋ₓS, MgₓCd₁₋ₓS, CaₓCd₁₋ₓS, SrₓCd₁₋ₓS, BaₓCd₁₋ₓS, HgₓCd₁₋ₓS, ScₓCd₁₋ₓS, AlₓCd₁₋ₓS, GaₓCd₁₋ₓS, InₓCd₁₋ₓS, MnₓCd₁₋ₓS, FeₓCd₁₋ₓS, NiₓCd₁₋ₓS, CuₓCd₁₋ₓS, MoₓCd₁₋ₓS, PdₓCd₁₋ₓS, AgₓCd₁₋ₓS, PtₓCd₁₋ₓS, AuₓCd₁₋ₓS, CdS, CdSe, CdTe, ZnS, ZnSe, ZnTe, MgS, MgSe, MgTe, HgS, HgSe, HgTe, PbS, PbSe, PbTe, AlN, AlP, AlAs, AlSb, GaN, GaP, GaAs, GaSb, InN, InP, InAs, InSb, TlN, TlP, TlAs, TlSb, and a combination thereof.

15. (canceled)

16. The method claim 1, wherein the isolating comprises isolating the nanocrystal quantum dot precipitate to obtain the nanocrystal quantum dot, wherein the nanocrystal quantum dot has an average diameter of about 2 nanometers to about 10 nanometers.

17. The method of claim 1, wherein the isolating comprises isolating the nanocrystal quantum dot precipitate to obtain the nanocrystal quantum dot, wherein the nanocrystal quantum dot exhibits a quantum yield (QY) of about 60% to about 90%.

18. The method of claim 1, wherein the isolating comprises isolating the nanocrystal quantum dot precipitate to obtain the nanocrystal quantum dot, wherein the nanocrystal quantum dot exhibits an emission wavelength of about 400 nanometers to about 2000 nanometers.

19. (canceled)

20. The method of claim 1, wherein heating the mixture comprises heating the mixture to a temperature of about 170° C. to about 300° C. at a rate of about 2° C. per minute to about 50° C. per minute for about 30 minutes to about 4 hours.

21-22. (canceled)

23. The method of claim 1, wherein the precipitating comprises cooling the mixture to a temperature of about −50° C. to about −100° C. and adding a polar solvent.

24-25. (canceled)

26. The method of claim 23, wherein adding the polar solvent comprises adding the polar solvent selected from the group consisting of dichloromethane (DCM), tetrahydrofuran, ethyl acetate, acetone, dimethylformamide, acetonitrile, dimethyl sulfoxide, formic acid, methanol, ethanol, butanol, and combinations thereof.

27. The method of claim 1, wherein isolating the nanocrystal quantum dot precipitate comprises isolating the precipitate by centrifuging the mixture.

28-31. (canceled)

32. A method of forming a nanocrystal comprising an outer shell encapsulating an inner core, the method comprising:
contacting a solvent comprising a first mixture of trioctylphosphine, stearic acid, and 1-octadecene with a second mixture comprising CdO, at least one cationic precursor, and at least one anionic precursor to form a third mixture;
heating the third mixture;
precipitating to form a nanocrystal precipitate; and
isolating the nanocrystal precipitate to obtain the nanocrystal.

33. The method of claim 32, wherein the contacting comprises contacting the solvent comprising the first mixture of trioctylphosphine, stearic acid, and 1-octadecene with the second mixture comprising CdO, the at least one anionic precursor, and the at least one cationic precursor selected from the group consisting of a group II metal, a group III metal, a group IV metal, and a combination thereof.

34. The method of claim 32, wherein the contacting comprises contacting the solvent comprising the first mixture of trioctylphosphine, stearic acid, and 1-octadecene with the second mixture comprising CdO, the at least one cationic precursor, and the at least one anionic precursor selected from the group consisting of a group V metal, a group VI metal, and a combination thereof.

35. The method of claim 32, wherein the contacting comprises contacting trioctylphosphine and the cationic precursor in a weight to weight ratio of about 0.001:1 to about 10:1.

36. The method of claim 32, wherein the contacting comprises contacting stearic acid and the cationic precursor in a weight to weight ratio of about 1:1 to about 4:1.

37. The method of claim 32, wherein isolating the nanocrystal precipitate comprises obtaining the nanocrystal wherein the nanocrystal core comprises a group II-VI compound, a group II-V compound, a group III-VI compound, a group III-V compound, a group IV-VI compound, a group I-III-VI compound, a group II-IV-VI compound, a group II-IV-V compound, or combinations thereof.

38. (canceled)

39. The method of claim 32, wherein isolating the nanocrystal precipitate comprises obtaining the nanocrystal wherein the nanocrystal shell comprises a group II-VI compound, a group II-V compound, a group III-VI compound, a group III-V compound, a group IV-VI compound, a group I-III-VI compound, a group II-IV-VI compound, a group II-IV-V compound, or combinations thereof.

40-42. (canceled)

43. The method of claim 32, wherein isolating the nanocrystal precipitate comprises obtaining the nanocrystal wherein the nanocrystal has an average diameter of about 2 nanometers to about 10 nanometers, and the nanocrystal exhibits a quantum yield (QY) of about 60% to about 90%.

44. (canceled)

45. The method of claim 32, wherein isolating the nanocrystal precipitate comprises obtaining the nanocrystal wherein the nanocrystal exhibits an emission wavelength of about 400 nm to about 2000 nm.

46. (canceled)

47. The method of claim 32, wherein heating the third mixture comprises heating the third mixture to a temperature of about 170° C. to about 300° C. at a rate of about 2° C. per minute to about 50° C. per minute for about 30 minutes to about 4 hours.

48-49. (canceled)

50. The method of claim 32, wherein the precipitating comprises cooling the third mixture to a temperature of about −50° C. to about −100° C. and adding a polar solvent.

51-53. (canceled)

54. The method of claim 32, wherein isolating the nanocrystal precipitate comprises isolating the precipitate by centrifuging the mixture.

55-58. (canceled)

59. The method of claim 1, wherein the method can be carried out as a one-pot reaction to obtain the nanocrystal quantum dot precipitate.
